(19) United States
(12) Patent Application Publication
(10) Pub. No.: US 2007/0290264 A1
(43) Pub. Date: Dec. 20, 2007

(54) SEMICONDUCTOR DEVICE AND A METHOD OF MANUFACTURING THE SAME

(76) Inventors: Nobuyuki Sugii, Tokyo (JP); Ryuta Tsuchiya, Hachioji (JP); Yusuke Morita, Hachioji (JP)

Correspondence Address: MILES & STOCKBRIDGE PC, 1751 PINNACLE DRIVE, SUITE 500, MCLEAN, VA, 22102-3833, US

(21) Appl. No.: 11/674,420

(22) Filed: Feb. 13, 2007

(30) Foreign Application Priority Data
Jun. 14, 2006 (JP) 2006-164620

(51) Int. Cl. H01L 29/786; H01L 21/336

(52) U.S. Cl. 257/348; 438/166; 257/E21.409; 257/E29.273

(57) ABSTRACT

The invention aims at increasing an effect of a strain applying technique for enhancing transistor performance in a fully depleted silicon-on-insulator (FDSOI) type transistor having a thin buried oxide (BOX) film. In an FDSOI type transistor having a very thin SOI structure (6), a stress generating region is formed on a back face side (5) of a very thin BOX layer (4) in order to apply strains to portions in which channels are intended to be formed. Desired portions on a back face side of the BOX layer (4) are amorphized by performing ion implantation, and are then recrystallized by performing a heat treatment in a state where a stress applying film (3) is formed, thereby transferring stresses from the stress applying film (3) to the portions in which the channels are intended to be formed. Thus, the stress generating region is formed.

### CROSS-REFERENCE TO RELATED APPLICATIONS

The present application claims priority from Japanese Patent Application JP 2006-164620 filed on Jun. 14, 2006, the content of which is hereby incorporated by reference into this application.

### BACKGROUND OF THE INVENTION

The present invention relates to a logic element for use in an electronic computer or an information communication apparatus, and more particularly to a silicon field effect semiconductor device.

In a silicon field effect semiconductor device for a logic element, an increase in integration density by minimizing elements, improvement in performance such as an operating speed, and reduction in a power consumption per element have been continuously carried out. However, an element has been downsized and is now required to have a processing size of about 50 nm. Thus, it is difficult to obtain the improvement in the performance and the reduction in the power consumption. To solve the problems, there are typical techniques such as a high dielectric constant gate insulating film or a high mobility channel obtained from strained silicon.

On the other hand, a new problem with the progress of downsizing of elements is that the degree of variability of elements has increased. When the degree of the variability increases, it becomes difficult to reduce a supply voltage from a viewpoint of requirement for ensuring a voltage margin required to normally operate all circuits. This results in that it becomes difficult to reduce the power consumption per element, so that the power consumption of a semiconductor chip having a high integration with the downsizing is increased. Moreover, the large degree of the variability considerably increases the power consumption of the overall chip due to an element having poor power consumption performance. For this reason, it becomes difficult to increase a circuit scale and a function by downsizing elements without changing the power consumption in the chip having the same area, which has been possible until now.

Japanese Patent Laid-open No. 2005-251776 discloses a silicon-on-insulator (hereinafter called SOI) technique capable of reducing the degree of variability of elements to remarkably improve the performance of the semiconductor chip. The SOI technique uses a substrate having a very thin SOI layer and a buried oxide (hereinafter called a “BOX”) layer so as to form a fully depleted SOI (hereinafter called an “FDSOI”) element. Also, a bias voltage is applied to a back face of the BOX layer so as to change a threshold voltage of the element. When the SOI technique is used, for example, it becomes possible to adjust the bias voltage of the chip which is nonuniform with a large power consumption after completion of the manufacture of the chip so that the bias voltage can be returned back to an appropriate value. This makes it possible to improve the yield of the chips. Moreover, if a circuit structure is adapted such that a chip is divided into a plurality of areas and that a bias voltage is automatically and independently adjusted for each of the plurality of areas, the power consumption of the chip can be further reduced because the characteristics of all the transistors within the chip are quite uniform.

### BRIEF SUMMARY OF THE INVENTION

It is thought that a combination of this FDSOI structure with the high dielectric constant gate insulating film or strained silicon described above makes it possible to improve the operating speed while the power consumption of the chip is reduced. However, it has become clear that the combination of the FDSOI element with the strained silicon technique causes several problems. The strained silicon technique is roughly classified into two kinds of techniques. A first technique is one using a strain called a substrate strain, a global strain or the like. Thus, with this first technique, an element is manufactured using a silicon substrate including an SiGe layer formed therein in a state in which a strain is previously applied to a portion functioning as a channel of the element. In addition, a second technique uses a strain called an external strain, a local strain or the like. Thus, with the second technique, in processes for manufacturing an element, a film to which a stress is to be applied is formed on an upper portion of the element, or buried in the element, thereby giving a strain to a channel. It is thought that the latter has a higher practicability than that in the former because a conventional substrate can be used as it is. As an external strain technique which is frequently used, an SiN liner film technique, a technique for burying SiGe (or SiC) in a source/drain region and a stress memorization method are known. Here, the SiN liner film technique, for example, is disclosed in a literary document of F. Ootsuka et al., IEDM technical Digest, p. 575, (2000). The technique for burying SiGe (or SiC) in a source/drain region, for example, is disclosed in a literary document of T. Ghani et al., Technical Digest IEDM 2003, p. 978, (2003). Also, the strain storing method, for example, is disclosed in a literary document of K. Ota et al., Technical Digest IEDM 2002, p. 27, (2002).

However, in the case of the FDSOI element, a elevated layer is grown in which an additional Si layer is epitaxially grown on an SOI layer of a source/drain region in order to reduce a parasitic resistance. Hence, even when an SiN liner film is disposed above a gate or the source/drain region, the SiN liner film and a channel are formed away from each other due to the presence of the elevated layer. As a result, there is encountered a problem such that the strain cannot be effectively applied to the channel. In addition, even if SiGe (or SiC) is attempted to be buried in the source/drain region, there is no room for the burying of SiGe (or SiC) in the source/drain region because the SOI layer is thin. Also, even when the elevated layer is made of SiGe, the strain applying layer is also formed away from the channel. As a result, there is caused a problem such that the strain applying effect is small. Moreover, in the case as well of the strain storing method, since the SOI layer of the FDSOI element is thin, a film becomes thin which can be amorphized by implanting ions into a source/drain portion. In addition, even when it is supposed that the elevated film is epitaxially grown in the manner as described above, the amorphized region is also formed away from the channel. As a result, there is encountered a problem such that the effect of the stress is reduced.

In the light of the foregoing, the present invention has been made in order to solve the above-mentioned problems, and it is therefore an object of the present invention to provide a field effect semiconductor device in which it is possible to apply a strain enough to contribute to an improvement in performance in an FDSOI structure, and a method of manufacturing the same.

In order to attain the above-mentioned object, according to the present invention, there is provided a semiconductor device having a fully depleted type insulated gate field effect transistor, the semiconductor device including: a semiconductor substrate; a first insulating film formed on the semiconductor substrate; a single crystal semiconductor thin film formed on the semiconductor substrate through the first insulating film; a gate electrode formed through a second insulating film formed on the single crystal semiconductor thin film; and a stress applying region formed in the semiconductor substrate on a back face side of the first insulating film.

Preferably, the stress applying region is selectively formed below a source/drain region of the fully depleted type insulated gate field effect transistor.

Moreover, in order to attain the above-mentioned object, the present invention provides the semiconductor device in which when the fully depleted type insulated gate field effect transistor has an NMOS transistor and a PMOS transistor, a stress applied by the stress applying region is a tensile stress in a region in which a channel of the NMOS transistor is formed, and is a compressive stress in a region in which a channel of the PMOS transistor is formed.

In addition, in order to attain the above-mentioned object, according to the present invention, there is provided a method of manufacturing a fully depleted type insulated gate field effect transistor including at least a single crystal semiconductor thin film formed through a first insulating film formed on a semiconductor substrate, and a gate electrode formed through a second insulating film formed on the single crystal semiconductor thin film, in which a predetermined region on a back face side of the first insulating film is amorphized and a stress is applied from an outside to the amorphized region when the amorphized region is recrystallized, thereby forming a stress applying region such that the stress is left in the predetermined region on the back face side of the first insulating film.

That is to say, the present invention provides the method of manufacturing a semiconductor device, the method including the steps of: forming an amorphized region in the semiconductor substrate on the back face side of the first insulating film; and recrystallizing the amorphized region in a state in which a stress is applied from an outside of the amorphized region.

Preferably, the step of forming an amorphized region is a step of amorphizing the predetermined region on the back face side of the first insulating film by utilizing an ion implantation method, and the step of recrystallizing the amorphized region is a step of recrystallizing processing using a heat treatment.

It should be noted that in the disclosure of the present invention, an insulating layer may be described as an insulating film, and a buried oxide (BOX) layer may be described as a BOX film or may be simply described as a BOX.

The structure is adopted in which there is formed the stress applying region for applying the stress to the back face through the BOX layer as the first insulating film, preferably, to the region on the back face side of the source/drain region. As a result, the BOX layer itself has a sufficient rigidity in the FDSOI structure having the thin BOX layer formed therein. Also, the BOX layer is close to the channel, and thus the stress can be efficiently applied to the channel.

That is to say, although the FDSOI structure has low variability of elements and is excellent in the short channel characteristics, the strain cannot be conventionally, effectively applied to the channel in order to improve the performance because of the thin SOI film. However, according to the present invention, even in the FDSOI structure, the optimal strains required for the improvement in the performance can be applied to the NMOS transistor and the PMOS transistor independently of each other. For this reason, the low variability reduces the power consumption in the standby state. Also, the improvement in mobility due to the effective application of the strain results in that the enhancement of the operating performance per power consumption. In other words, the reduction in the power consumption in the same operating state becomes possible. As a result, it is possible to realize both the low power consumption and high performance operation of the very highly integrated semiconductor circuit.

### BRIEF DESCRIPTION OF THE SEVERAL VIEWS OF THE DRAWINGS

FIG. 1 is a cross sectional view explaining the principles of the present invention;

FIG. 2 is a cross sectional view explaining a process for manufacturing a semiconductor device according to a first embodiment of the present invention;

FIG. 3 is a cross sectional view explaining a process for manufacturing the semiconductor device according to the first embodiment of the present invention;

FIG. 4 is a cross sectional view explaining a process for manufacturing the semiconductor device according to the first embodiment of the present invention;

FIG. 5 is a cross sectional view explaining a process for manufacturing the semiconductor device according to the first embodiment of the present invention;

FIG. 6 is a cross sectional view explaining a process for manufacturing the semiconductor device according to the first embodiment of the present invention;

FIG. 7 is a cross sectional view explaining a process for manufacturing the semiconductor device according to the first embodiment of the present invention;

FIG. 8 is a cross sectional view explaining a process for manufacturing the semiconductor device according to the first embodiment of the present invention;

FIG. 9 is a cross sectional view explaining a process for manufacturing the semiconductor device according to the first embodiment of the present invention;

FIG. 10 is a cross sectional view explaining a process for manufacturing the semiconductor device according to the first embodiment of the present invention;

FIG. 11 is a cross sectional view explaining a process for manufacturing the semiconductor device according to the first embodiment of the present invention;

FIG. 12 is a cross sectional view explaining a process for manufacturing the semiconductor device according to the first embodiment of the present invention;

FIG. 13 is a cross sectional view explaining a process for manufacturing the semiconductor device according to the first embodiment of the present invention;

FIG. 14 is a cross sectional view showing a state of completion of the processes for manufacturing the semiconductor device according to the first embodiment of the present invention;

FIG. 15 is a cross sectional view explaining processes for manufacturing a semiconductor device according to a second embodiment of the present invention;

FIG. 16 is a cross sectional view explaining a process for manufacturing a semiconductor device according to a third embodiment of the present invention;

FIG. 17 is a cross sectional view explaining a process for manufacturing the semiconductor device according to the third embodiment of the present invention;

FIG. 18 is a cross sectional view explaining a process for manufacturing the semiconductor device according to the third embodiment of the present invention;

FIG. 19 is a cross sectional view explaining a process for manufacturing the semiconductor device according to the third embodiment of the present invention;

FIG. 20 is a cross sectional view explaining a process for manufacturing the semiconductor device according to the third embodiment of the present invention;

FIG. 21 is a cross sectional view explaining a process for manufacturing the semiconductor device according to the third embodiment of the present invention;

FIG. 22 is a cross sectional view explaining a process for manufacturing the semiconductor device according to the third embodiment of the present invention;

FIG. 23 is a cross sectional view explaining a process for manufacturing the semiconductor device according to the third embodiment of the present invention;

FIG. 24 is a cross sectional view explaining a process for manufacturing the semiconductor device according to the third embodiment of the present invention;

FIG. 25 is a cross sectional view explaining a process for manufacturing the semiconductor device according to the third embodiment of the present invention;

FIG. 26 is a cross sectional view showing a state of completion of the processes for manufacturing the semiconductor device according to the third embodiment of the present invention;

FIG. 27 is a cross sectional view explaining a process for manufacturing a semiconductor device according to a fourth embodiment of the present invention;

FIG. 28 is a cross sectional view explaining a process for manufacturing the semiconductor device according to the fourth embodiment of the present invention;

FIG. 29 is a cross sectional view explaining a process for manufacturing the semiconductor device according to the fourth embodiment of the present invention;

FIG. 30 is a cross sectional view explaining a process for manufacturing the semiconductor device according to the fourth embodiment of the present invention;

FIG. 31 is a cross sectional view explaining a process for manufacturing the semiconductor device according to the fourth embodiment of the present invention;

FIG. 32 is a cross sectional view explaining a process for manufacturing the semiconductor device according to the fourth embodiment of the present invention; and

FIG. 33 is a plan view explaining an arrangement direction of semiconductor elements in a semiconductor device according to a fifth embodiment of the present invention.

### DETAILED DESCRIPTION OF THE INVENTION

Prior to giving a description with respect to detailed embodiments, a description will now be given with respect to an outline of a method of applying a stress to a desired region on a back face side of a BOX layer of the present invention. Although there are a plurality of application methods, a common point among them is as follows. That is to say, a predetermined region on a back face side of a BOX layer is previously amorphized by utilizing an ion implantation method. Then, while the amorphized region is recrystallized by performing a heat treatment, a stress is applied from the outside to the amorphized region, so that the stress is left in the amorphized region on the back face side of the BOX layer.

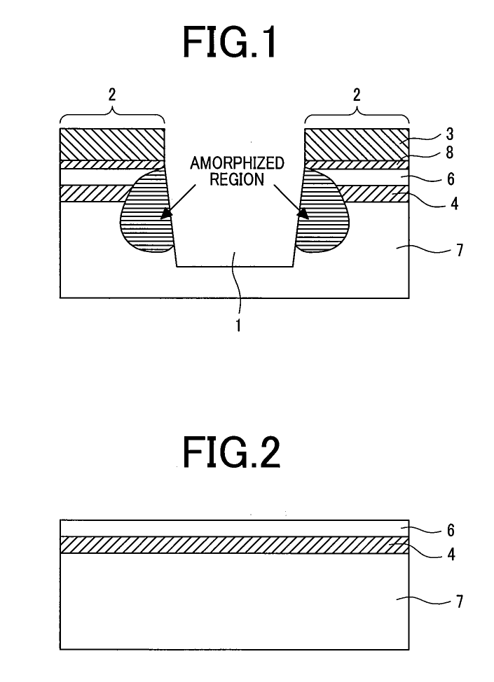

Now, in a first stress applying method, a predetermined region on a back face side of a BOX layer is amorphized by implanting ions into a portion of the back face side of the BOX layer contacting an end face of an isolation trench in a state in which the isolation trench is previously formed. An outline of the first stress applying method will now be described with reference to FIG. 1. An isolation trench 1 is formed by utilizing a dry etching method. In this state, a silicon nitride (SiN) film 3 is formed in an upper portion of an active region 2 in which an element is intended to be formed. In this case, the SiN film 3 is sufficiently thick in order to act as an etching stopper in a subsequent chemical mechanical polishing (hereinafter called “CMP”) process. In this state, when ions are implanted, preferably, in an oblique direction, the ions are not implanted into the active region 2, but are implanted into a back portion 5 of the BOX layer 4 and end portions of an SOI layer 6. Here, the back portion 5 of the BOX layer 4 and the end portions of the SOI layer 6 contact end faces of the isolation trench 1. As a result, the back portion 5 of the BOX layer 4 and the end portions of the SOI layer 6 are amorphized. After that, silicon dioxide (SiO₂) is filled in the isolation trench 1 at a temperature at which the amorphized portions are not crystallized. In this state, a heat treatment is performed for the purpose of increasing a density of SiO₂ thus filled therein as performed in a normal process. In this heat treatment process, the above-mentioned amorphized portions are crystallized. A stress accompanying the increase in density of SiO₂, and a stress in SiN as the etching stopper 3 are both applied. After completion of the above-mentioned heat treatment, similarly to a normal process, the SiO₂ layer is flattened by utilizing the CMP method until the SiN etching stopper 3 is exposed. Subsequently, a process for removing the SiN etching stopper 3 is performed, thereby completing an isolation process.

The control for the application direction of the strain is important from a viewpoint of an improvement in the performance of the transistor. For an N-channel metal oxide semiconductor (NMOS) transistor, a tensile strain is preferably applied in parallel with a current direction of a channel. In addition, for a P-channel metal oxide semiconductor (PMOS) transistor, conversely, a compressive strain is preferably applied in parallel with the current direction of the channel. Therefore, it is preferable to adopt processes for applying a different stress to each of the NMOS region and the PMOS region. While details will be described in later embodiments, the first stress applying method enables the above processes to be performed. The SiN etching stopper film 3 can arbitrarily change an application direction and a magnitude of a stress depending on its formation condition. Therefore, an SiN film which generates a tensile stress may be formed in the NMOS region, and an SiN film which applies a compressive stress may be formed in the PMOS region. When the SiN film which generates the tensile stress is desired to be firstly formed in the NMOS region, after formation of the SiN film in the NMOS region, the SiN film may be removed only from the PMOS region through a photolithography process. Also, similarly, after formation of the SiN film for applying the compressive stress in the PMOS region, the SiN film may be removed only from the NMOS region. During this process, there is no need for preparing any of excessive masks in addition to a normal process. In the normal process, a mask used to divide an active region into the NMOS region and the PMOS region is generally prepared for formation of a source/drain region. Thus, this mask may be utilized in this process. The same processes as those for a normal complementary metal oxide semiconductor (CMOS) can be used after completion of the isolation process.

In the second stress applying method, an isolation region, a gate electrode, and an offset spacer are formed by utilizing the normal method. After that, before a process for forming an extension region, the amorphization is performed for a supporting substrate on a back face side of a BOX layer in a self-align manner by utilizing an ion implantation method. An SOI layer of a source/drain region is also amorphized in the phase of the amorphization. However, as will be described in detail in the later embodiments, the crystalline of the SOI layer of a channel region is held. Thus, the crystalline of the source/drain region can also be recovered by performing the heat treatment. Next to the ion implantation for the amorphization, impurity ions are implanted into the extension region as well. During this process, for the NMOS transistor, a gate stress can be applied by implanting As ions into the gate as well. After that, a heat treatment is performed after formation of a liner film for stress application, thereby performing activation of the extension region and recrystallization of the back side portions of the SOI layer and the BOX layer. In this process, either the liner film or the gate applies the strain to the channel. Similarly to the first stress applying method, the stress applied from either the liner film or the gate can be separately controlled for the NMOS region and the PMOS region. After that, the liner film thus formed may be used as a gate sidewall film just as it is. Or, after removal of the liner film, a gate sidewall film may be newly formed. After completion of this process, the same processes as those in the normal CMOS can be used.

A projected range of the implanted ions, that is, a depth of the amorphized portion is preferably nearly equal to a gate length or about 2 times as large as the gate length when being measured from a back side interface of the BOX layer. In the substrate, for a semiconductor element, as an object of the present invention, normally, a thickness of the SOI layer falls within the range of 5 to 100 nm, and a thickness of the BOX layer falls within the range of 5 to 50 nm. For example, when the gate length is 40 nm, and the thickness of each of the SOI layer and the BOX layer is 10 nm, it is recommended that the depth of the ion implantation is set in the range of about 40 to about 80 nm from the back side interface of the BOX layer and is set in the range of about 60 to about 100 nm from a surface of the SOI layer. From a viewpoint of application of the stress, it may safely be said that it is better to perform the amorphization until the deeper portion is reached. On the other hand, from a viewpoint of avoidance of generation of crystal defects in the phase of recrystallization, it is desirable that the better, the shallower the portion which is amarphized is. Thus, when the balance between both the viewpoints is taken into consideration, the depth range as described above is suitable.

The ion species which are implanted in the amorphizing process are preferably the group IV elements from a standpoint of holding a carrier concentration of a semiconductor constant. The implantation of the ions of Si as the same material as that of the substrate makes it possible to efficiently perform only the amorphization. In addition, only either one of Ge ions or C ions can be implanted, or can be implemented together with the Si ions. When the Ge ions are implanted, the compressive stress can be applied to the region into which the Ge ions were implanted because an atomic radius of a Ge atom is larger than that of an Si atom. Thus, the process for implanting the Ge ions is suitable for the PMOS. On the other hand, when C ions are implanted, contrary to the above case, the tensile stress can be applied to the region into which the C ions were implanted. Thus, the process for implanting the C ions is suitable for the NMOS.

In order to obtain the maximum strain application effect, selection of a surface orientation and a current direction in the channel is also important. Although (100) oriented silicon is normally used in the channel, in order to enhance the performance while the compatibility with a circuit library which has been used until now is held, the selection of the surface orientation is important as first selection. In the case of the NMOS transistor in which the tensile strain is applied to the impurity ion-implanted region, the current direction in this case has a larger effect in a <100> crystal orientation than in a <110> crystal orientation. In the case of the PMOS transistor in which the compressive stress is applied to the impurity ions-implanted region, conversely, the current direction has a larger effect in the <110> crystal orientation than in the <100> crystal orientation. However, in the case of the PMOS transistor, the characteristics of a micro-transistor when the strain is hardly applied are more excellent in <100> rather than in <110>. Thus, the <100> crystal orientation is preferable when the strain is nearly equal to or lower than 2,000 MPa in the channel position having a less amount of strain applied thereto, and the <110> crystal orientation is preferable when the strain is equal to or larger than 2,000 MPa in the channel region. In the latter case, the channel direction is rotated between the NMOS transistor and the PMOS transistor by 450. The rotation of the channel direction is not desirable in terms of a circuit layout. Therefore, it is preferable that the <100> crystal orientation be used in a circuit in which the NMOS performance is regarded as important, and the <110> crystal orientation be used in a circuit such as an SRAM in which the balance between the NMOS transistor performance and the PMOS transistor performance is regarded as important.

When the performance is aimed at being improved to the maximum, a region may be formed in which a crystal orientation of the SOI layer is rotated by 45°, and this region, for example, may be used only in the PMOS transistor. This process can be attained as follows. That is to say, the SOI substrate in which the crystal orientation of the supporting substrate on the back face side of the BOX layer is rotated by 45° is used, and the original SOI layer (which is different in crystal orientation from the supporting substrate) is selectively removed in a portion in which that SOI region is intended to be formed. After that, a part of the BOX layer is opened, and a film having the same crystal orientation as that of the supporting substrate is epitaxially grown on the BOX layer by utilizing an epitaxial lateral overgrowth (ELO) method. As a result, the above-mentioned process can be attained. Note that, although a portion which is obtained by opening the part of the BOX layer becomes a seed crystal for the ELO process, if this portion is utilized in the form of the isolation region, no chip area is excessively consumed.

Moreover, when the NMOS region and the PMOS region are given the different crystal orientations, respectively, setting (110) as a surface orientation of the PMOS channel results in the largest performance enhancement being obtained. At this time, the channel direction is also preferably made to match the <110> crystal orientation. To sum up, for the channel surface orientation and the channel current direction in which the maximum performance can be expected, the tensile strain for the combination of the (100) surface orientation and the <100> crystal orientation is obtained in the NMOS transistor, and the compressive strain for the combination of the (110) surface orientation and the <110> crystal orientation is obtained in the PMOS transistor.

Note that, when a description is necessary in the detailed embodiments for the sake of convenience, the description will be divided into a plurality of sections or embodiments. However, the plurality of sections or embodiments have some connection with one another except for the case where they are especially stated clearly, but one is connected with changes, details and a supplementary explanation of a part or all of the other. In addition, when reference is made to the number of elements, or the like (including the number of constituent elements, numeric values, amounts, ranges and the like) in the following embodiments, the present invention is not intended to be limited to the specific number thereof except for the case where they are especially stated clearly and the case where they are clearly limited to the specific number in principles. Thus, the number of elements may be equal to or larger than a specific number or may be equal to or smaller than the specific number. Moreover, it goes without saying that in the following embodiments, constituent elements thereof (including constituent steps) are necessarily essential to the present invention except for the case where they are especially stated clearly and the case where they are thought to be clearly essential to the present invention in principles. Likewise, when in the following embodiments, reference is made to shapes and positional relationships of constituent elements or the like, elements or the like which are substantially approximate or similar to the shapes or the like of the constituent elements or the like are included in the present invention except for the case where they are especially stated clearly and the case where they are thought not to be clearly so in principles. This is also applied to the numeric values and range described above. In addition, the constituent elements which have the same functions in all the figures for explanation of the following embodiments are designated with the same reference numerals, respectively, and their repeated descriptions are omitted here for the sake of simplicity.

The detailed embodiments of the present invention will be described hereinafter with reference to the accompanying drawings. It is to be understood that materials, conductivity types, manufacturing conditions and the like of portions are not intended to be limited to those described in the following embodiments of the present invention, and the various changes of the embodiments may be made.

### First Embodiment

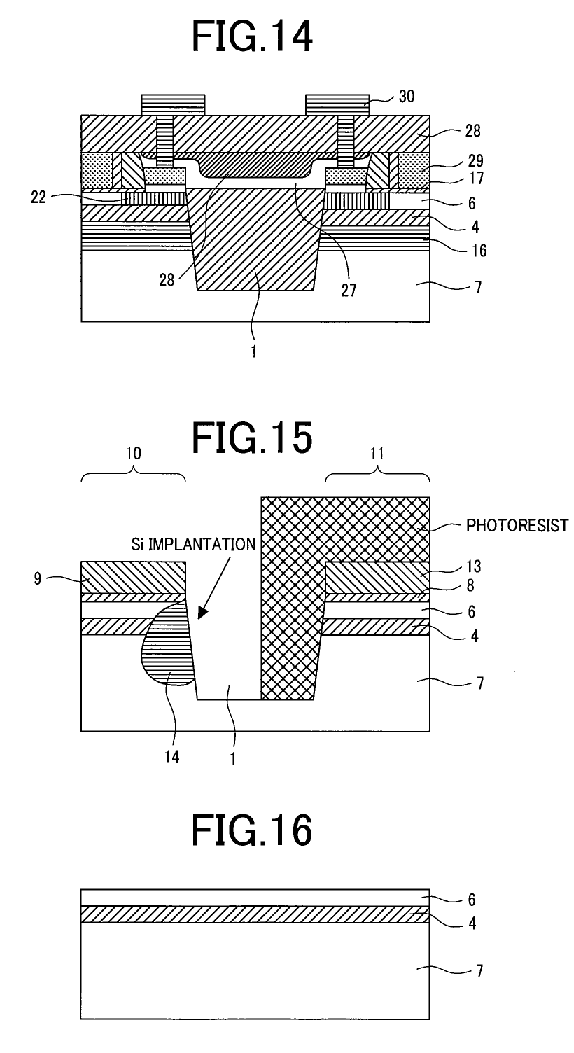

A first embodiment of the present invention uses the first stress applying method described above. FIGS. 2 to 13 are respectively cross sectional views showing processes for manufacturing a semiconductor device according to the first embodiment of the present invention in respective manufacturing stages in order. Also, FIG. 14 is a cross sectional view showing a state of completion of the processes for manufacturing the semiconductor device according to the first embodiment of the present invention.

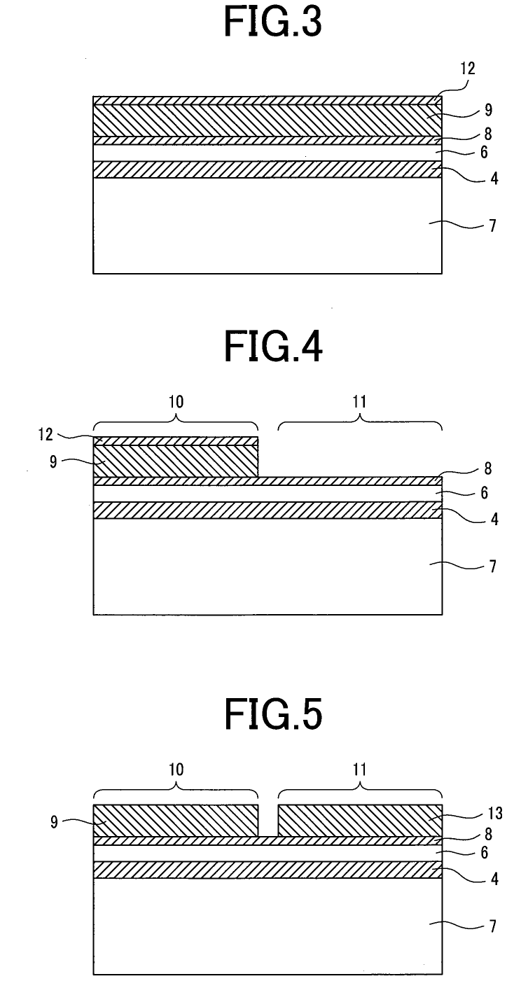

An SOI substrate including an SOI layer 6 with 30 nm thickness and a BOX layer 4 with 10 nm thickness as shown in FIG. 2 is prepared. At this time, it is assumed that a surface orientation of a supporting substrate 7 is (100) and a surface orientation of the SOI layer 6 is (100). In addition, it is assumed that a crystal orientation of the SOI layer 6 parallel with an orientation flat or a notch of the supporting substrate 7 is <100>. Firstly, a surface of the supporting substrate 7 is cleaned, an SiO₂ layer with 10 nm thickness is formed by oxidizing the surface of the supporting substrate 7. Also, an SiN etching stopper film 9 and an SiO₂ layer 12 are formed to have a thickness of 100 nm and a thickness of 10 nm, respectively, under a condition in which a tensile stress is generated. FIG. 3 shows the above state. Next, after an NMOS region 10 is coated with a photoresist by utilizing a photolithography technique, the SiO₂ layer 12 and the SiN etching stopper film 9 of a PMOS region 11 are removed by utilizing a chemical etching method, and the photoresist of the PMOS region 11 is also removed. FIG. 4 shows this state. Next, a second SiN etching stopper 13 is formed. A thickness of the second SiN etching stopper 13 is set to 100 nm. Also, the second SiN etching stopper film 13 is formed under a condition in which a compressive stress is generated. After the PMOS region 11 is coated with a photoresist again by utilizing the photolithography technique, the SiN etching stopper film 13 and the SiO₂ layer 12 of the NMOS region 10 are removed by utilizing the chemical etching method, and the photoresist of the NMOS region 10 is also removed. FIG. 5 shows this state. In the photolithography process for the NMOS region 10 and the PMOS region 11, sizes of the NMOS region 10 and the PMOS region 11 are reduced to the extent that they exceed an alignment precision by adjusting an exposure condition, so that even when the SiN etching stopper layers 9 and 13 formed on the PMOS region 10 and the NMOS region 11, respectively, cause the misalignment, they do not overlap each other.

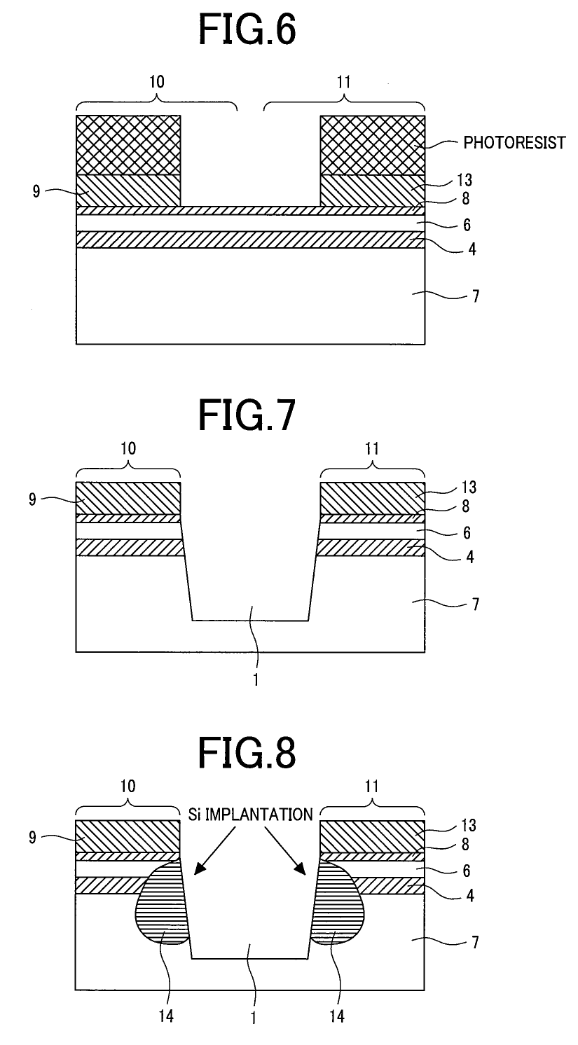

Next, after an active region 2 is coated with a photoresist by utilizing the photolithography technique for forming an isolation trench 1, a part of the first and second SiN etching stopper films 9 and 13 is removed by utilizing a dry etching method. FIG. 6 shows this state. After the photoresist is removed, the SiO₂ layer 8, the SOI layer 6, the BOX layer 4 and the supporting substrate 7 are subjected to the dry etching in this order by using the remaining first and second SiN etching stopper films 9 and 13 as an etching mask, thereby forming the isolation trench 1. A depth of the isolation trench 1 is set to about 300 nm. FIG. 7 shows this state. In order to prevent kink characteristics of the transistor, rounding a shape of an end portion of the isolation trench 1 by in situ steam generation (issg) oxidation processing is performed for an inner surface of the isolation trench 1. By performing this process, the change in the stresses of the first and second SiN etching stopper films 9 and 13 become negligibly small.

Next, Si ions are implanted at an acceleration voltage of 50 keV at an angle of 25° when viewed from a direction vertical to a substrate surface. At this time, a range of the implanted species is about 70 nm. Si of a portion into which the Si ions are implanted with a dose of 1e15/cm² is sufficiently amorphized. FIG. 8 shows this state, including amorphized regions 14. In this state, a tensile stress and a compressive stress are applied to the first and second SiN etching stopper films 9 and 13, respectively. This stress state hardly changes in the above-mentioned process.

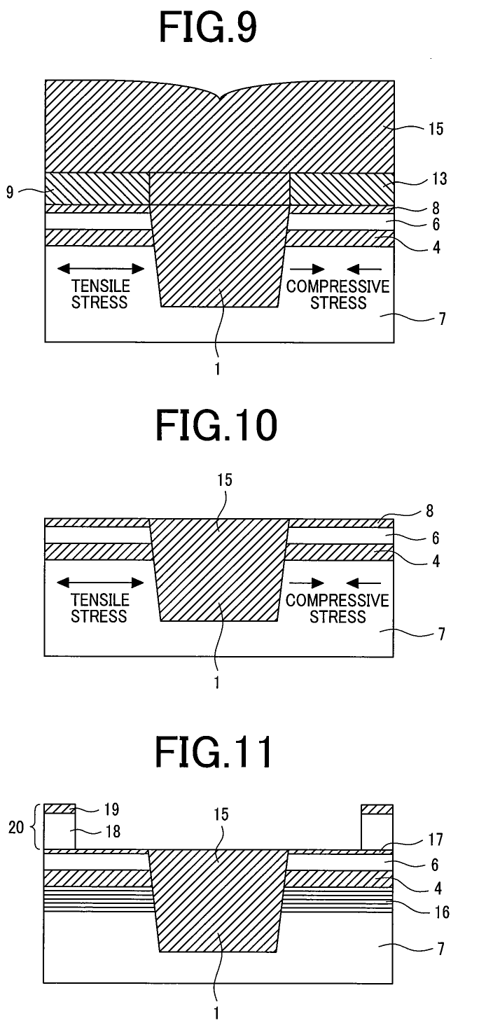

Next, an SiO₂ film 15 using a tetraethoxysilane (TEOS) raw material is formed over the whole surface, including the isolation trench 1, to have a thickness of 600 nm. Moreover, a densification heat treatment for an oxide film is performed at 1,100° C. for 30 minutes. In this process, the above-mentioned amorphized regions 14 are crystallized, and at the same time, desired stresses are applied to portions adjacent to the amorphized regions 14, respectively. FIG. 9 shows this state. A layout for the isolation region and the active region is made so that a current direction of a channel matches a <110> crystal orientation with respect to the crystal orientation of the SOI film 6.

Hereinafter, after completion of the same processes as those of the normal case, a CMOS transistor is manufactured. These processes will now be described in brief. The SiO₂ film 15 is polished until the first and second SiN etching stopper films 9 and 13 are exposed, and the first and second SiN etching stopper films 9 and 13 are then removed by utilizing the chemical etching method. FIG. 10 shows this state. Next, impurity ions are implanted into a well 16. At this time, an implantation depth reaches inside the supporting substrate 7 on the back face side of the BOX layer 4. Next, for diffusion and activation of the well impurities, a heat treatment is then performed. However, there is no change in the strains applied in the above-mentioned process because the stress state is fixed by the isolation oxide film 15. After formation of the well 16, a gate insulating film 17 as a second insulating film, a polycrystalline silicon film 18 for a gate electrode, and an oxide film 19 for gate protection are formed in order. After a gate pattern is formed by utilizing the photolithography technique, a gate electrode 20 is defined by utilizing the dry etching method. FIG. 11 shows this state. However, for each of the NMOS transistor and the PMOS transistor, a part of the transistor, that is, only a gate and one of a source region and a drain region are illustrated in FIG. 11. The reason for this is because the source region and the drain region are normally formed symmetrically with respect to the gate. However, there may be some increase or decrease in size. In the following figures, only a part of each of the NMOS transistor and the PMOS transistor will also be illustrated.

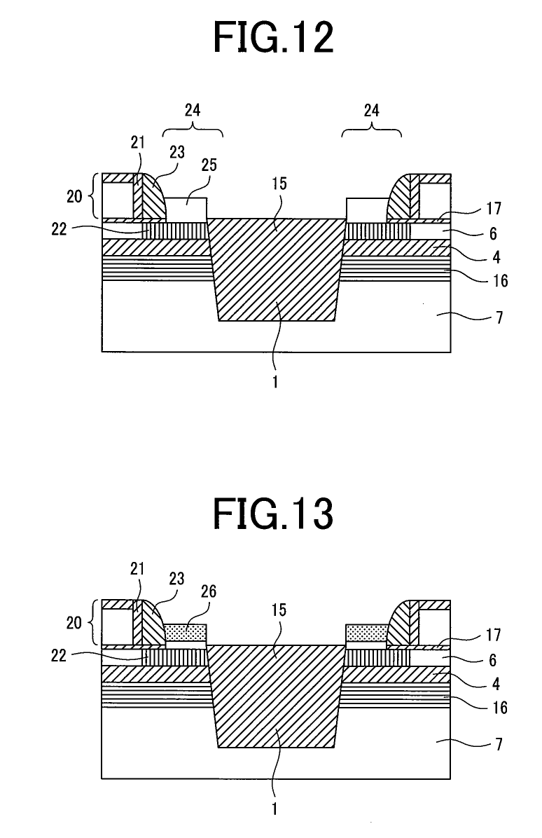

Subsequently, there are performed a process for forming an offset spacer 21, a process for forming an extension region 22, a process for forming a gate sidewall 23, and a process for epitaxially growing an Si elevated layer 25 on a source/drain region 24. FIG. 12 shows a cross section in this state. Next, deep ion implantation for formation of the source/drain region 24 is performed, and a rapid heat treatment for activating the impurity is performed. In this process as well, the strains hardly change. Next, a part of the Si elevated layer 25 of the source/drain region 24 is made to turn into an NiSi layer 26. At this time, since the gate 20 and the gate sidewall 23 portion are coated with the SiO₂ film, no NiSi reaction occurs in the gate 20 and the gate sidewall 23 portion. FIG. 13 shows this state. Moreover, an SiN film 27 which becomes an etching stopper when contact holes for the gate 20 and the source/drain region 24 are formed, and an interlayer insulating film 28 are formed. After that, the polycrystalline silicon film 18 in a gate electrode 20 portion is exposed by utilizing the CMP method, and the NiSi reaction is made to occur. At this time, an Ni film having a sufficient thickness is deposited, and a heat treatment is then performed for a suitable time, which results in that all the polycrystalline silicon film of the gate portion turns into an NiSi layer 29. After completion of the formation of the NiSi layer 29, the excessive Ni film is removed and an additional interlayer insulating film 28 is formed to have a desired thickness. After that, a first wiring layer 30 is formed. FIG. 14 shows this state. Since the subsequent wiring process is the same as that performed by utilizing an existing technique, a description thereof is omitted here for the sake of simplicity.

### Second Embodiment

A semiconductor device according to a second embodiment of the present invention will be described in detail hereinafter with reference to FIG. 15. Only points of difference from the first embodiment will now be described in the second embodiment. The second embodiment adopts the same processes as those in the first embodiment up to the process for forming the isolation trench 1 shown in FIG. 7 of the first embodiment. In a process next thereto, after a mask for defining an NMOS region 10 is formed and a PMOS region 11 is coated with a photoresist, firstly, Si ions are implanted at an acceleration voltage of 50 keV at an angle of 650. At this time, a projected range of the implantation species is about 70 nm. Si of a portion into which the Si ions are implanted with a dose of 1e15/cm² is sufficiently amorphized. Subsequently, C ions are implanted at an acceleration voltage of 22 keV at an angle of 250 when viewed from a direction vertical to a substrate surface. At this time, a projected range of the implantation species is about 70 nm. This portion is doped with C with a dose of 1e15/cm². However, a thickness of a photoresist is set to 0.3 μm so that the implanted C ions are not shielded by the photoresist. FIG. 15 shows this state. Next, after the photoresist is removed, a mask for defining the PMOS region 11 is formed and the NMOS region 10 is coated with a photoresist. After that, Ge ions are implanted at an acceleration voltage of 100 keV at an angle of 250 when viewed from a direction vertical to the substrate surface. At this time, a projected range of the implanted species is about 70 nm. Si of a portion into which the Ge ions are implanted with a dose of 1e16/cm² is sufficiently amorphized and this portion is doped with Ge. Next, the photoresist is removed. Subsequent processes are the same as those in the first embodiment. In the manner described above, the implantation of the impurity ions from Si in the first embodiment to Ge or C (when the C ions are implanted, the implantation of the Si ions is performed together therewith for the amorphization) makes it possible to increase the stress as compared with that in the first embodiment by about 20%.

### Third Embodiment

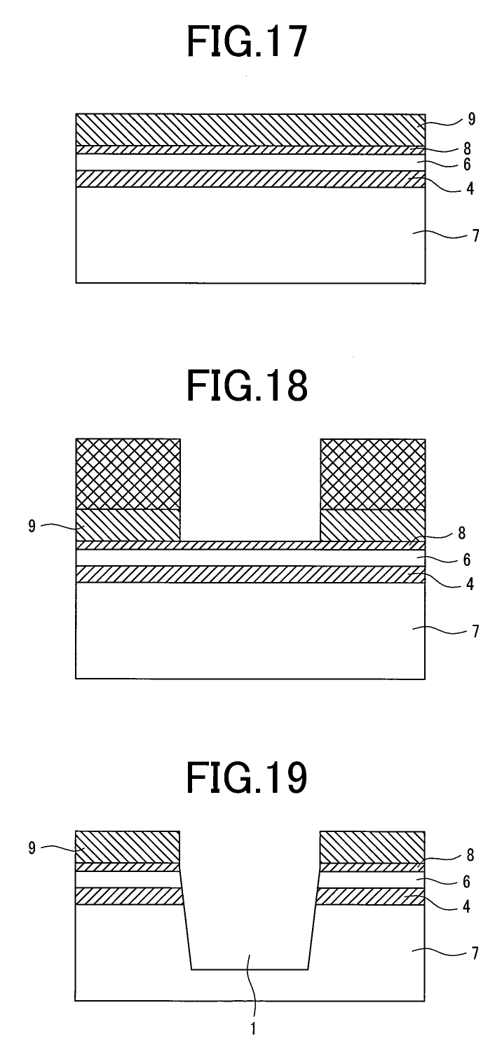

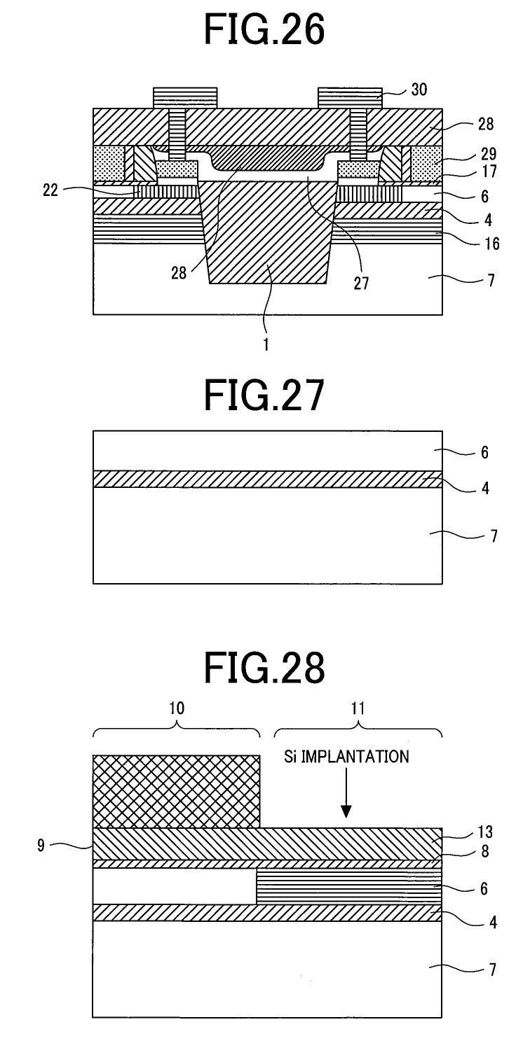

Next, a detailed description will now be given with respect to a third embodiment utilizing the second stress applying method, that is, the method of implanting the impurity ions into the supporting substrate on the back face side of the BOX layer in the self-align manner by using the gate electrode as the mask. FIGS. 16 to 25 are respectively cross sectional views showing processes for manufacturing a semiconductor device according to the third embodiment of the present invention in respective manufacturing stages in order. Also, FIG. 26 is a cross sectional view showing a state of completion of the processes for manufacturing the semiconductor device according to the third embodiment of the present invention. An SOI substrate including an SOI layer 6 with 30 nm thickness and a BOX layer 4 with 10 nm thickness as shown in FIG. 16 is prepared. At this time, it is assumed that a surface orientation of a supporting substrate 7 is (100) and a surface orientation of the SOI layer 6 is (100). In addition, it is assumed that a crystal orientation of the SOI layer 6 parallel with an orientation flat or a notch of the supporting substrate 7 is <100>. Firstly, a surface of the supporting substrate 7 is cleaned, an SiO₂ layer with 10 nm thickness is formed by oxidizing the surface of the supporting substrate 7. Moreover, an SiN etching stopper film 9 is formed to have a thickness of 100 nm under a condition in which a stress is small. FIG. 17 shows this state. Next, after the photolithography process for forming an isolation trench 1 is carried out and an active region 2 is coated with a photoresist, a part of the SiN etching stopper film 9 is removed by utilizing the dry etching method. FIG. 18 shows this state. After the photoresist is removed, the SiO₂ layer 8, the SOI layer 6, the BOX layer 4 and the supporting substrate 7 are subjected to the dry etching in this order by using the remaining SiN etching stopper film 9 as an etching mask, thereby forming the isolation trench 1. A depth of the isolation trench 1 is set to about 300 nm. FIG. 19 shows this state. In order to prevent kink characteristics of the transistor, rounding a shape of an end portion of the isolation trench 1 by in situ steam generation (issg) oxidation processing is performed for an inner surface of the isolation trench 1 for a very short time.

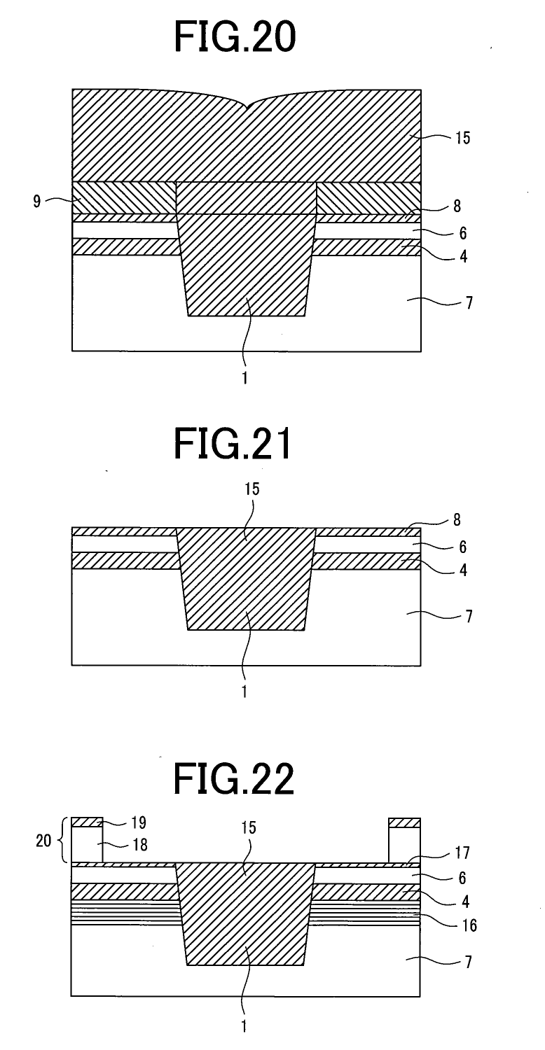

Next, an SiO₂ film 15 using the TEOS raw material is formed over the whole surface, including the isolation trench 1, to have a thickness of 600 nm. Moreover, a densification heat treatment for an oxide film is performed at 1,100° C. for 30 minutes. FIG. 20 shows this state. A layout of the isolation region and the active region is made so that a current direction of a channel matches a <110> crystal orientation with respect to the crystal orientation of the SOI film.

Next, the SiO₂ film 15 is polished until the SiN etching stopper film 9 is exposed, and the remaining SiN etching stopper film 9 is then removed by utilizing the chemical etching method. FIG. 21 shows this state. Next, impurity ions are implanted into a well 16. At this time, an implantation depth reaches inside the supporting substrate 7 on the back face side of the BOX layer 4. Next, for diffusion and activation of the well impurities, a heat treatment is then performed. After completion of the formation of the well 16, a gate insulating film 17, a polycrystalline silicon film 18 for a gate electrode, and an oxide film 19 for gate protection are formed in order. After a gate pattern is formed by utilizing the photolithography technique, a gate electrode 20 is defined by utilizing the dry etching method. FIG. 22 shows this state. Moreover, an offset spacer 21 is formed.

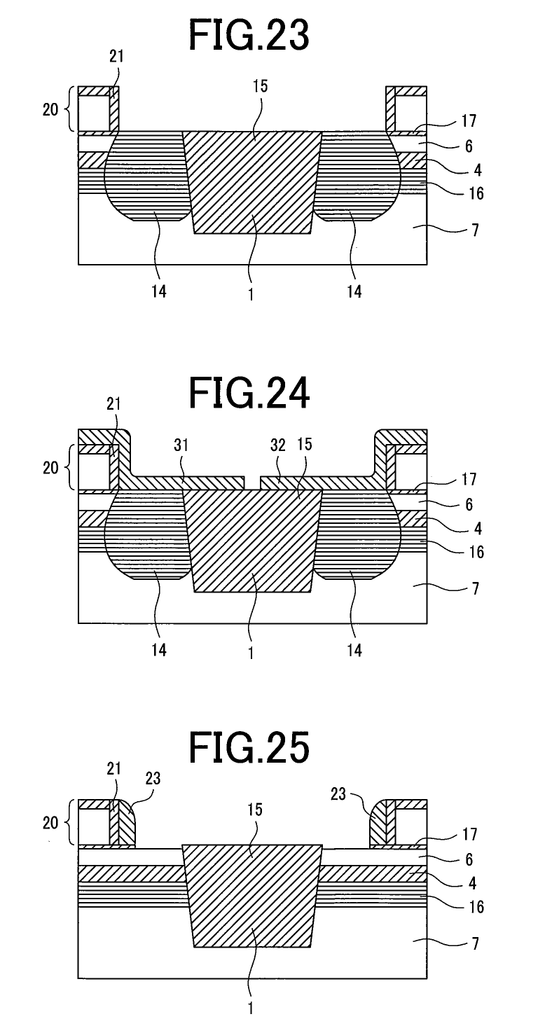

Before impurity ions are implanted in order to form an extension region 22, Si ions are implanted into a back face portion of the BOX layer 4 formed below a source/drain region 24 at an acceleration voltage of 60 keV at an angle of 600 by using the gate electrode 20 as a mask. Si of a portion into which the Si ions are implanted with a dose of 1e15/cm² is sufficiently amorphized. FIG. 23 shows this state, including the amorphized regions 14. Next, ions are implanted in order to form an extension region 22 by utilizing a normal ion implantation method. In this case, As ions and BF₂ ions are selectively implanted into the NMOS region and the PMOS region, respectively, by using a photoresist as a mask. In each of the cases, an acceleration voltage is set to 3 keV and a dose is set to 1e15/cm².

Next, a first SiN liner film 31 for generating a tensile stress, and a second SiN liner film 32 for generating a compressive stress are formed in the NMOS region and the PMOS region, respectively, in order to form gate sidewalls 23 by utilizing the same method as that shown in the first embodiment. FIG. 24 shows a cross section in this state. Here, a heat treatment for activation of the impurity in the extension region, and recrystallization of the back face of the BOX layer is performed for a short time. As a result, the first and second SiN liner films 31 and 32 apply the tensile stress and the compressive stress to the channel of the NMOS region and the channel of the PMOS region, respectively. Next, the first and second SiN liner films 31 and 32 are etchbacked to be formed into the gate sidewalls 32, respectively. FIG. 25 shows a cross section in this state.

Hereinafter, the same processes as those in the first embodiment 1 will be performed. That is to say, subsequently, there is performed the process for epitaxially growing an Si elevated layer 25 on the source/drain region 24. Next, deep ion implantation for formation of the source/drain region 24 is performed, and a rapid heat treatment for activating the impurity is performed. In this process as well, the strains hardly change. Next, a part of the Si elevated layer 25 epitaxially grown on the source/drain region 24 is made to turn into an NiSi layer 26. At this time, since the gate 20 and the gate sidewall 23 portion are coated with the SiO₂ film, no NiSi reaction occurs in the gate 20 and the gate sidewall 23 portion. Moreover, an SiN layer 27 which becomes an etching stopper when contact holes for the gate 20 and the source/drain region 24 are formed, and an interlayer insulating film 28 are formed. After that, the polycrystalline silicon film 18 in a gate electrode 20 portion is exposed by utilizing the CMP method, and the NiSi reaction is made to occur in the polycrystalline silicon film 18. At this time, an Ni film having a sufficient thickness is deposited, and a heat treatment is then performed for a suitable time, which results in that all the polycrystalline silicon film 18 of the gate electrode 20 portion turns into an NiSi layer 29. After completion of the formation of the NiSi layer 29, the excessive Ni film is removed and an additional interlayer insulating film 28 is formed to have a desired thickness. After that, a first wiring layer 30 is formed. FIG. 26 shows this state. Since the subsequent wiring process is the same as that performed by utilizing the existing technique, a description thereof is omitted here for the sake of simplicity.

### Fourth Embodiment

FIGS. 27 to 31 are respectively cross sectional views showing processes for manufacturing a semiconductor device according to a fourth embodiment of the present invention in respective manufacturing stages in order. An SOI substrate including an SOI layer 6 with 60 nm thickness and a BOX layer 4 with 10 nm thickness as shown in FIG. 27 is prepared. At this time, it is assumed that a surface orientation of a supporting substrate 7 is (100) and a surface orientation of the SOI layer 6 is (100). In addition, it is assumed that a crystal orientation of the SOI layer 6 parallel with an orientation flat or a notch of the supporting substrate 7 is <100>, and a crystal orientation of the SOI layer 6 is <100>. Firstly, a surface of the supporting substrate 7 is cleaned, an SiO₂ layer 8 with 50 nm thickness is formed by oxidizing the surface of the supporting substrate 7. Subsequently, a first SiN etching stopper 9 with 100 nm thickness and a second SiN etching stopper film 13 with 100 nm thickness are formed in an NMOS region 10 and a PMOS region 11, respectively, by utilizing the same method as that in the first embodiment.

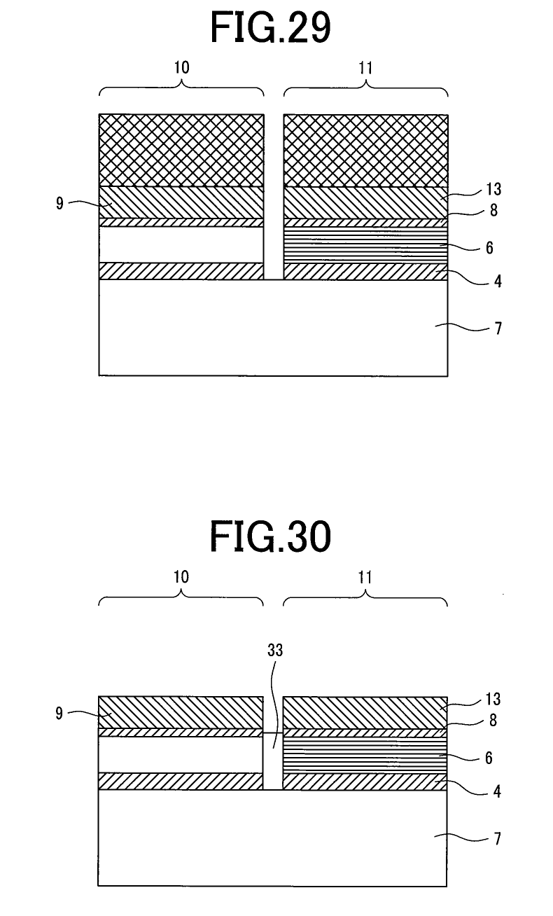

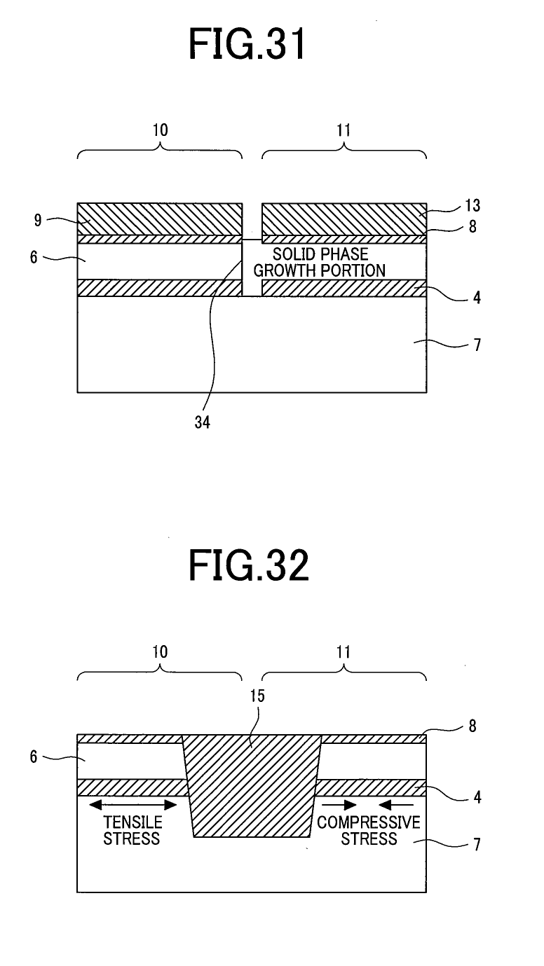

Next, after a photoresist mask is formed on a portion in which the NMOS region 10 is defined, Si ions are implanted vertically to the substrate surface at an acceleration voltage of 130 keV with a dose of 1e15/cm². As a result, the SOI layer 6 only in the PMOS region 11 is amorphized. FIG. 28 shows this state. After the photoresist mask is removed, the SOI layer 6 and the BOX layer 4 only in one side of a boundary portion between the PMOS region 11 and the NMOS region 10 are removed with another photoresist mask by utilizing the dry etching method. FIG. 29 shows this state. Next, an amorphous Si layer 33 is selectively grown so as to be partially filled in the portion from which the SOI layer 6 and the BOX layer 4 have been removed. Since the portions other than the resulting opening are coated with the SiO₂ layer 8, no amorphous Si layer is grown thereon. FIG. 30 shows this state. Moreover, a heat treatment is performed at 800° C. for 30 minutes, which results in the amorphous Si layer 33 being crystallized. At this time, since the supporting substrate 7 acts as the seed crystal, the resulting crystallized Si layer has the same (100) surface orientation as that of the SOI layer 6 in the NMOS region 10. However, the crystal orientation of the resulting crystallized Si layer parallel with the orientation flat or the notch of the supporting substrate 7 becomes <110> because the intra-plain crystal orientation is rotated by 45°. FIG. 31 shows this state. Crystal grain boundaries 34 are formed in the boundary portion between the NMOS region 10 and the PMOS region 11.

Next, a photoresist mask for formation of an isolation trench 1 is formed, and the isolation trench 1 for an isolation region is formed by the same dry etching method as that in the first embodiment 1. All the opening portion and the crystal grain portion which have irregularities are removed in this process. FIG. 32 shows this state. Since the subsequent processes are the same as those in the first embodiment, their descriptions are omitted here for the sake of simplicity. After completion of the process shown in FIG. 32, in the NMOS region 10, the surface orientation of the channel becomes (100) and the channel direction matches <100>, and in the PMOS region 11, the surface orientation of the channel becomes (100) and the channel direction matches <110>.

### Fifth Embodiment

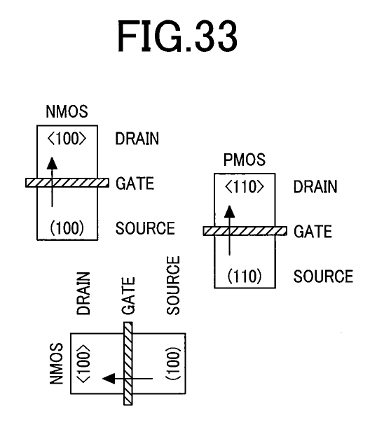

In a fifth embodiment, only points of difference from the fourth embodiment 4 will be described in detail hereinafter. Although a prepared substrate has the same film structure as that in the fourth embodiment, it is assumed that a surface orientation of the supporting substrate 7 is (100), and a surface orientation of the SOI layer 6 is (100). In addition, it is assumed that a crystal orientation of the supporting substrate 7 parallel with an orientation flat or a notch of the supporting substrate 7 is <110>, and a crystal orientation of the SOI layer 6 is <100>. All the subsequent processes are the same as those in the fourth embodiment. After completion of that process, in the NMOS region 10, a surface orientation of the channel becomes (100) and the channel direction matches <100>, and in the PMOS region 11, a surface orientation of the channel becomes (100) and the channel direction matches <110>. In this case, a layout of the transistors is set as shown in FIG. 33. That is to say, the PMOS transistor is laid out in a direction in which the channel direction usually matches <110>. When the PMOS transistor is laid out in a direction vertical to that direction, a channel direction matches <100>. However, the use of the transistor laid out in that orientation is not limited from a viewpoint of the control for the current characteristics of the transistor.

When the insulated gate type semiconductor device according to each of the first to fifth embodiments of the present invention which have been described in detail so far is used in the electronic information apparatus or electronic computer having a logic circuit and the like mounted thereto, the power consumption of the electronic information apparatus or the electronic computer can be greatly reduced and also the processing performance thereof can be improved. Note that, the various inventions disclosed in the paragraph of “DETAILED DESCRIPTION OF THE INVENTION” which has been described so far are described in brief as follows.

The fully depleted type insulated gate field effect transistor includes at least the single crystal semiconductor thin film and the gate electrode, the single crystal semiconductor thin film being formed through the first insulating film formed on the semiconductor substrate, the gate electrode being formed through the second insulating film formed on the single crystal semiconductor thin film; and the stress applying region is formed within the semiconductor substrate on the back face side of the first insulating film.

The stress applying region is selectively formed below the source/drain region.

The stress applying region is recrystallized in the state where a stress is applied to the amorphized region from the portion other than the amorphized region, thereby generating the stress.

The stress applying region preferably generates the stress by implanting the group IV semiconductor atoms.

The group IV semiconductor atoms are applied to the stress applying region from the side face of the isolation trench.

The group IV semiconductor atoms are applied to the stress applying region through the single crystal semiconductor thin film and the first insulating film from the upper portion of the single crystal semiconductor thin film in the source/drain region.

The stress is applied by the thin film formed on the single crystal semiconductor thin film.

The stress is applied by the material buried in the trench of the isolation region.

The stress applied by the stress applying film is the tensile stress in the region in which the NMOS transistor is intended to be formed, and is the compressive stress in the region in which the PMOS transistor is intended to be formed.

The stress applying film serves also as the etching stopper in the process for forming the isolation region.

In the state in which the insulator region is formed, the tensile stress is applied to the single crystal semiconductor thin film in the NMOS formation region surrounded by the isolation region, and the compressive stress is applied to the single crystal semiconductor thin film in the PMOS formation region surrounded by the isolation region.

The surface orientation of the semiconductor substrate is (100), the surface orientation of the single crystal semiconductor thin film is (100) in the region in which the NMOS transistor is intended to be formed, and the crystal orientation of the single crystal semiconductor thin film parallel with the current direction of the NMOS channel is <100>. In addition, the surface orientation of the single crystal semiconductor thin film in the region in which the PMOS transistor is intended to be formed is (100), and the crystal orientation of the single crystal semiconductor thin film parallel with the current direction of the PMOS channel is <110>.

The surface orientation of the semiconductor substrate is (110), the surface orientation of the single crystal semiconductor thin film in the region in which the NMOS transistor is intended to be formed is (100) and the crystal orientation of the single crystal semiconductor thin film parallel with the current direction of the NMOS channel is <100>. In addition, the surface orientation of the single crystal semiconductor thin film in the region in which the PMOS transistor is intended to be formed is (110), and the crystal orientation of the single crystal semiconductor thin film parallel with the current direction of the PMOS channel is <110>.

Furthermore, the surface orientation of the semiconductor substrate may be (100), the surface orientation of the single crystal semiconductor thin film in the region in which the NMOS transistor is intended to be formed may be (100), and the crystal orientation of the single crystal semiconductor thin film parallel with the current direction of the NMOS channel may be <100>. In addition, the surface orientation of the single crystal semiconductor thin film in the region in which the PMOS transistor is intended to be formed may be (110), and the crystal orientation of the single crystal semiconductor thin film parallel with the current direction of the PMOS channel may be <110>.

The single crystal semiconductor thin film in the region in which the NMOS transistor is intended to be formed is amorphized, and is then recrystallized in the same direction as the crystal orientation of the semiconductor substrate. As a result, the surface orientation of the single crystal semiconductor thin film in the region in which the NMOS transistor is intended to be formed is (100), and the crystal orientation of the single crystal semiconductor thin film parallel with the current direction of the NMOS channel is <100>.

The single crystal semiconductor thin film in the region in which the PMOS transistor is intended to be formed is amorphized, and is then recrystallized in the same direction as the crystal orientation of the semiconductor substrate. As a result, the surface orientation of the single crystal semiconductor thin film in the region in which the PMOS transistor is intended to be formed is (100), and the crystal orientation of the single crystal semiconductor thin film parallel with the current direction of the PMOS channel is <110>.

The single crystal semiconductor thin film in the region in which the PMOS transistor is intended to be formed is amorphized, and is then recrystallized in the same direction as the crystal orientation of the semiconductor substrate. As a result, the surface orientation of the single crystal semiconductor thin film in the region in which the PMOS transistor is intended to be formed is (110), and the crystal orientation of the single crystal semiconductor thin film parallel with the current direction of the PMOS channel is <110>.

What is claimed is:

1. A semiconductor device having a fully depleted type insulated gate field effect transistor, the semiconductor device comprising:
a semiconductor substrate;
a first insulating film formed on the semiconductor substrate;
a single crystal semiconductor thin film formed on the semiconductor substrate through the first insulating film;
a gate electrode formed through a second insulating film formed on the single crystal semiconductor thin film; and
a stress applying region formed in the semiconductor substrate on a back face side of the first insulating film.

2. A semiconductor device according to claim 1, wherein the stress applying region is selectively formed below a source/drain region of the fully depleted type insulated gate field effect transistor.

3. A semiconductor device according to claim 1, wherein the fully depleted type insulated gate field effect transistor has an NMOS transistor and a PMOS transistor, and a stress by applied the stress applying region is a tensile stress in a region in which a channel of the NMOS transistor is formed, and is a compressive stress in a region in which a channel of the PMOS transistor is formed.

4. A method of manufacturing a semiconductor device having a fully depleted type insulated gate field effect transistor including at least a single crystal semiconductor thin film formed through a first insulating film formed on a semiconductor substrate, and a gate electrode formed through a second insulating film formed on the single crystal semiconductor thin film, the method comprising the steps of:
forming an amorphized region in the semiconductor substrate on a back face side of the first insulating film; and
recrystallizing the amorphized region in a state in which a stress is applied from a portion other than the amorphized region.

5. A method of manufacturing a semiconductor device according to claim 4, wherein the step of forming an amorphized region is a step of amarphizing a predetermined region on the back face side of the first insulating film by utilizing an ion implantation method.
